(19) United States
(12) Patent Application Publication
(10) Pub. No.: US 2011/0165338 A1
(43) Pub. Date: Jul. 7, 2011

(54) APPARATUS FOR FORMING SOLDER DAM

(75) Inventors: Masayuki KITAJIMA, Kawasaki (JP); Yutaka NODA, Kawasaki (JP); Hidehiko KOBAYASHI, Kawasaki (JP); Toshihiro KUSAGAYA, Shinagawa (JP); Kazuhiro MIZUKAMI, Shinagawa (JP)

(73) Assignees: FUJITSU LIMITED, Kawasaki-shi (JP); FUJITSU COMPONENT LIMITED, Tokyo (JP)

(21) Appl. No.: 12/977,641

(22) Filed: Dec. 23, 2010

(30) Foreign Application Priority Data
Jan. 5, 2010 (JP) 2010-000696

(51) Int. Cl. B05D 1/32; B05C 11/00; B05B 5/025; C25D 17/00; B05D 5/00; C23C 14/34; C25D 5/02; B05D 1/04

(52) U.S. Cl. 427/468; 118/504; 204/298.11; 118/621; 204/242; 427/58; 204/192.15; 205/118

(57) ABSTRACT

An apparatus for forming a solder dam on each lead of an electronic device includes a mask having one or more slits; and forming means that forms the solder dam made of non-metal material on the lead of the electronic device through the slits of the mask.

### CROSS-REFERENCE TO RELATED APPLICATIONS

This application is based upon and claims the benefit of priority of the prior Japanese Patent Application No. 2010-00 0696, filed on Jan. 5, 2010, the entire contents of which are incorporated herein by reference.

### FIELD

The embodiments discussed herein are related to form a solder dam on a lead of an electronic device.

### BACKGROUND

A process called reflow soldering is known as one of schemes of mounting an electronic device to a printed board. In reflow soldering, an electronic device is disposed on a board on which a solder paste has been coated or printed, the entire board is heated and thereby the solder is molten in a heating device called a reflow oven, so that the leads of the electronic devices are grafted to predetermined positions on the board. A reflow oven includes, for example, a far-infrared heater or a warm-air heater, and precisely controls the temperature in the oven to evenly melt the solder on the board.

The wettability (the mobility and the spreadability) of molten solder varies with temperature of a portion to which the solder is to adhere. Even when the temperature in the reflow oven is uniform, the difference in heat capacity between the board and the leads causes the temperature of the leads to be higher than the temperature of lands on the board that the leads are to be grafted to. In this case, the solder molten on the board is drawn up through the surface of the leads toward the resin shield of the electronic device, that is, a so-called drawing-up phenomenon occurs, so that the leads tend to be poorly grafted to the lands of the printed board.

One of the known solutions to this problem, a solder resist layer is formed on the surface of each leads to prevent the solder from being drawn up. In this technique, leads are immersed into a solder resist solution to form a resist layer coating on the surface of the leads; and the resist layer formed on the tips of the leads are removed using a remover solution so that solder grafting portions are formed on the tip of the leads. Namely, covering the leads except the tips thereof with a resist layer prevents the solder from being drawn up.

Besides the above, another known solution applies fluorine or silicone to the circumference of leads to prevent solder from being drawn up. Specifically, a solder bumper (i.e., corresponding to a solder dam) to which solder does not adhere is formed on each leads, so that the molten solder is prevented from being drawn up from the tip of the leads to the ends coupled to the electronic device (e.g. Japanese Patent Application Laid-Open Publication NO 2000-261134).

However, the former technique once forms the resist layer on a portion that does not require the solder dam, solder adheres to such a portion and removed afterward is wasted, increasing production costs. Since the resist layer left after the removal serves as a solder dam, the accuracy of dimension of the solder dam is affected by various factors, such as the viscosity of the solder resist, the concentration of the remover solution, and accuracy in applying the remover solution. For this reason, it is difficult to form delicate solder dams and therefore the technique has difficulty in application to a minute leads arranged in narrow pitches.

In the latter technique, the accuracy in forming a solder dam depends on the accuracy in applying fluorine or silicone. The latter technique therefore has a difficulty in forming delicate solder dams.

### SUMMARY

According to an embodiment of the invention, an apparatus for forming a solder dam on each lead of an electronic device, the apparatus includes a mask having one or more slits; and sputtering means that forms the solder dam made of inorganic material on the lead of the electronic device through the slits of the mask through sputtering.

Furthermore, there is disclosed an apparatus for forming a solder dam on each lead of an electronic device, the apparatus including: a mask having one or more slits; and electrodepositing means that electrodeposites electrified resin material on the lead of the electronic device through the slits of the mask.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1A is a perspective view of the entire configuration of an example of a semiconductor package fabricated by an apparatus for forming a solder dam according to a first embodiment;

FIG. 1B is an enlargement view of a main part of semiconductor package fabricated by an apparatus for forming a solder dam of the first embodiment;

FIG. 2 is a perspective view of a lead frame used by an apparatus for forming a solder dam of the first embodiment;

FIG. 3 is a plane view of an example of the configuration of an apparatus for forming a solder dam of the first embodiment;

FIG. 4 is a perspective view schematically illustrating an example of a depositing unit of an apparatus for forming a solder dam of the first embodiment;

FIG. 5 is a perspective view schematically illustrating an example of a sputtering shield mask of an apparatus for forming a solder dam of the first embodiment;

FIG. 6 is a flow diagram illustrating a succession of procedural steps of forming solder dams on leads by an apparatus for forming a solder dam of the first embodiment;

FIG. 7A is a diagram illustrating an example of surface mounting of a semiconductor package fabricated by an apparatus for forming a solder dam of the first embodiment;

FIG. 7B is a diagram illustrating an example of through-hole mounting of a semiconductor package fabricated by an apparatus for forming a solder dam of the first embodiment;

FIG. 8 is a diagram schematically illustrating a depositing unit included in an apparatus for forming a solder dam of a first modification of the first embodiment;

FIG. 9 is a diagram schematically illustrating a depositing unit included in an apparatus for forming a solder dam of a second modification of the first embodiment;

FIG. 10 is a plane view of an example of the configuration of an apparatus for forming a solder dam according to a second embodiment;

FIG. 11 is a perspective view schematically illustrating a depositing unit included in an apparatus for forming a solder dam of the second embodiment;

FIG. 12 is a diagram schematically illustrating an example of the configuration of a spray shield mask of an apparatus for forming a solder dam of the second embodiment;

FIG. 13 is a plane view of an example of the configuration of an apparatus for forming a solder dam according to a third embodiment;

FIG. 14 is a side view schematically illustrating a depositing unit included in an apparatus for forming a solder dam of the third embodiment;

FIG. 15 is an exploded perspective view illustrating the configuration of an electrodeposition shield mask included in an apparatus for forming a solder dam serving as one example of the third embodiment;

FIG. 16 is a perspective view illustrating the configuration of an electrodeposition shield mask included in an apparatus for forming a solder dam serving as another example of the third embodiment;

FIG. 17 is a sectional view of the section A of FIG. 16;

FIG. 18 is a sectional view of the section B of FIG. 16; and

FIG. 19 is a perspective view illustrating a modification of a lead frame used in forming a solder dam.

### DESCRIPTION OF THE EMBODIMENTS

Hereinafter, description will now be made in relation to forming a solder dam according to embodiments and modifications with reference to accompanying drawings. However, the embodiments to be detailed below are merely example, so there is no intention of excluding another embodiments and variations and application of techniques that are not mentioned in this specification. In other words, various changes and modifications (e.g., combination of the embodiments and the modifications) can be suggested without departing from the spirit of the present embodiment.

### (A) Overview of a Solder Dam

The apparatus for forming a solder dam adopting a method of forming a solder dam of the embodiments forms solder dams on leads of an electronic device. A solder dam is made of a material to which solder hardly adheres, and therefore has a function of a barrier of flow of molten solder.

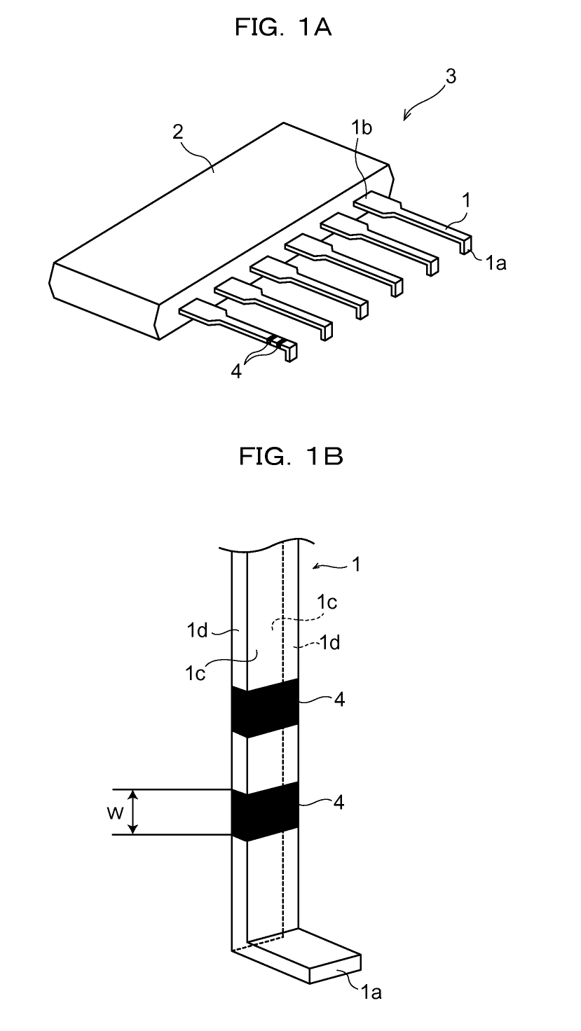

For example, as illustrated in FIGS. 1A and 1B, solid dams 4 are formed around the outer circumference of each lead 1, which extends from a resin shield 2 of an semiconductor package (electronic device) 3 to exterior of the shield 2, at intermediate portions on the lead 1 such that the lead 1 is divided into a tip 1a and a base 1b. The solder dams 4 can be a surface that inhibits solder from physically moving (i.e., drawing up from the tip 1a of the lead 1 to the base 1b).

The lead 1 is, as illustrated in FIG. 1A, a plate element formed by stamping (stamping shaping) a metal plate with a precision trimming die.

Hereinafter, the surfaces of each lead 1 on the plate surface are called surfaces 1c and the sections (narrower surfaces) formed in the thickness direction of the plate are called side faces 1d.

Each of the solder dams 4 illustrated in FIGS. 1A and 1B traverses the two surfaces 1c and the two side faces 1d, and the portions of each solder dam 4 formed on respective surfaces and faces communicate with one another such that the solder dam 4 enclose the circumference of the lead 1.

In the example of FIG. 1B, two solder dams 4 are formed on each lead 1 in two rows along the direction from the tip 1a to the base 1b of the lead 1. Namely, in the example of FIG. 1B, two parallel solder dams 4 are formed on each lead 1.

Alternatively, a solder dam 4 may be formed on part of the two surfaces 1c and the two side faces 1d, as substitute for the solder dam 4 formed on all the surfaces 1c and the side faces 1d as illustrated in FIG. 1B.

The width (dam width) W of each solder dam 4 is arbitrarily determined, but is preferably in a range of 0.1 through 1.0 mm both inclusive.

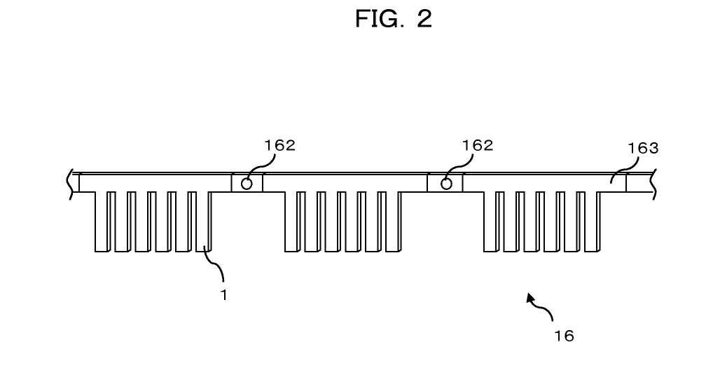

FIG. 2 is a perspective view of a lead frame used in a process of forming a solder dam of one of the embodiments.

As illustrated in FIG. 2, a lead frame 16 includes a number of strap-shaped frames 163 from each of which a number of leads 1 arranged at regular intervals extend in parallel in the same direction (downward in the example of FIG. 2), so that the leads are coupled in a strap shaped.

In the example of FIG. 2, the lead frame 16 includes transferring holes 162 at an interval of a predetermined number of leads 1 (at every six leads 1 in the illustrated example in FIG. 2).

FIG. 2 illustrates the leads 1 on which the solder dams 4 are not formed, and simplifies the shapes of the leads 1 and the entire lead frame 16 for convenience. The following embodiments and modifications are detailed with reference to such simplified lead frame 16.

### (B) Embodiments

### 1. First Embodiment

1-1. Configuration:

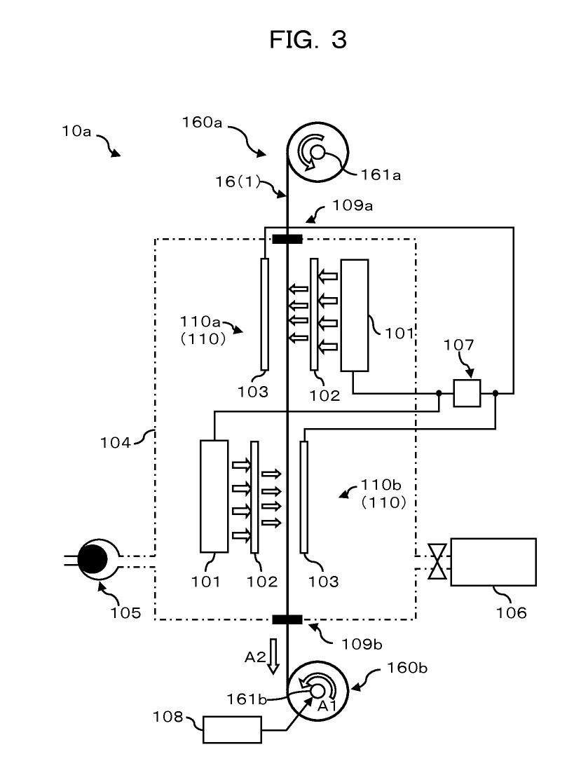

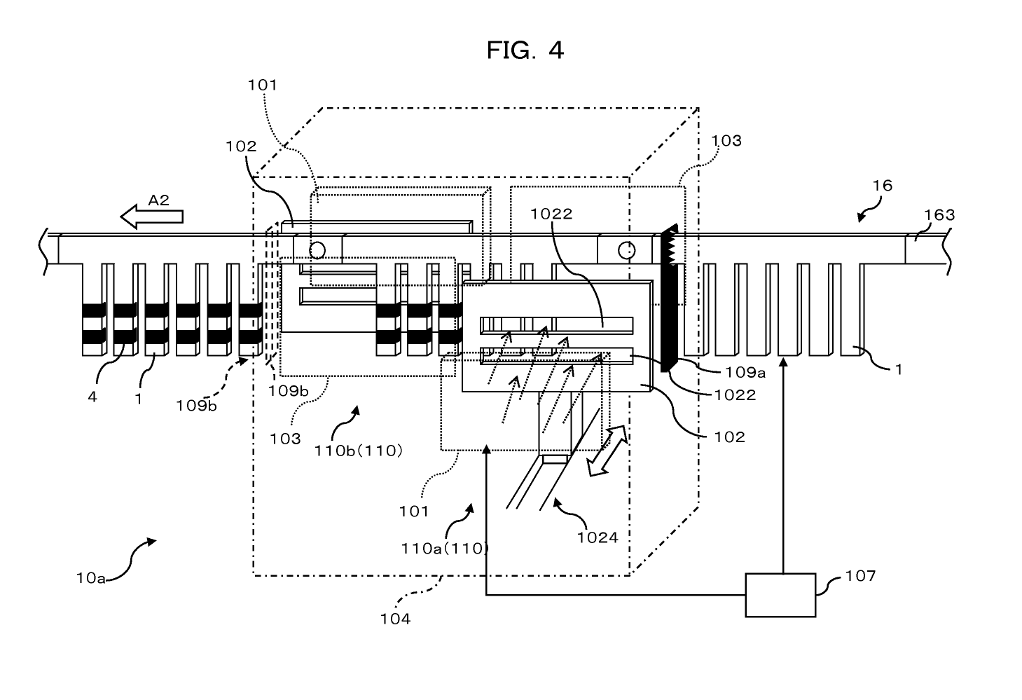

FIG. 3 is a plane view illustrating the configuration of an apparatus 10a of forming a solder dam serving as one example of a first embodiment; and FIG. 4 is a perspective view illustrating a depositing unit of the apparatus 10a. The apparatus 10a transfers the lead frame 16 and forms the solder dam 4 on the surfaces 1c, 1c of each lead 1 included in the lead frame 16 through a thin-film deposition process.

Hereinafter, an example will be detailed which uses sputtering process as the thin-film deposition process.

The apparatus 10a for forming a solder dam of the first embodiment, as illustrated in FIG. 3, includes a vacuum chamber 104, a first depositing unit 110a, a second depositing unit 110b, and a motor 108.

In the apparatus 10a, the lead frame 16 is configured to be reeled around an axis 161a of a mount 160a into a roll shape and to be unreeled the lead frame 16 reeled into the roll shape.

The unreeled lead frame 16 from the mount 160a is fixed to an axis 161b of another mount 160b disposed at the opposite side of the vacuum chamber 104 to the first mount 160a. Thereby, the lead frame 16 extends between the axes 161a and 161b.

Then, the first depositing unit 110a and the second depositing unit 110b form solder dams 4 on the lead frame 16 extending between the axes 161a and 161b.

The motor 108 is a driving device that rotates the axis 161b included in the second mount 160b in a predetermined direction (in the example of FIG. 3, in the direction of arrow A1). The motor 108 rotates the axis 161b in the predetermined direction at a predetermined speed, and thereby reels the lead frame 16 around the axis 161b and transfers the lead frame 16 extending between the axes 161a and 161b along a transferring direction (see arrow A2 in the example of FIG. 3). Namely, the motor 108 serves to function as a transferring unit that transfers the lead frame 16.

In the apparatus 10a for forming a solder dam, the lead frame 16 is mounted and transferred in such a posture that the leads 1 are extending downward in the vertical direction from the frames 163 as illustrated in FIG. 4.

Furthermore, the apparatus 10a for forming a solder dam includes a non-illustrated transferring guide (non-illustrated transferring guide), which positions the lead frame 16 and guides the lead frame 16 being transferred by the motor 108, and additionally stretches the lead frame 16 to apply a predetermined tension to the lead frame 16.

The transfer guide positions and guides the lead frame 16 by suspending the lead frame 16 with the aid of guide pins (not illustrated) inserted into the guide holes 162 on the frame 163 at predetermined positions between the axes 161a and 161b and unreels the lead frame 16 in harmony with transferring the lead frame 16 by the motor 108. Transferring, guiding, and positioning of the lead frame 16 can be realized by various known manners, and the detailed description thereof is omitted here.

The vacuum chamber 104 is a device that is capable of maintaining the inside thereof in a vacuum or substantially vacuum state. The vacuum chamber 104 is connected to a vacuum pump 105 and a gas supplying unit 106. The vacuum pump 105 makes the inside the vacuum chamber 104 vacuum and substantially vacuum, and is exemplified by a rotary pump. The vacuum chamber 104 is configured through which the lead frame 16, extending between the axes 161a and 161b, penetrates. The gas supplying unit 106 supplies the inside of the vacuum chamber 104 with inert gas such as argon (Ar).

As illustrated in FIG. 3, the vacuum chamber 104 includes a vacuum chamber shutter 109a on the end (upstream end) through which the lead frame 16 enters and a vacuum chamber shutter 109b on the other end (downstream end) through which the lead frame 16 is ejected from the vacuum chamber 104. The vacuum chamber shutters 109a and 109b are, for example, rubber packing, which elastically deforms so as to conform to the shape of the lead frame 16, keeping intimate contact with the lead frame 16. This configuration prohibits outside air from entering the inside of the vacuum chamber 104.

A first depositing unit 110a and a second depositing unit 110b are disposed inside the vacuum chamber 104. The first depositing unit 110a forms a solder dam 4 on one surface 1c of the lead frame 16 while the second depositing unit 110b forms a solder dam 4 on the other surface 1c of the lead frame 16.

In the apparatus 10a for forming a solder dam, the second depositing unit 110b is disposed downstream of the first depositing unit 110a with respect to the transferring direction (see arrow A2) of the lead frame 16.

The first depositing unit 110a and the second depositing unit 110b are substantially the same in configuration. Hereinafter, the both depositing units are sometimes simply called the “depositing units 110” for convenience when the common configuration and the common effects of the first depositing unit 110a and the second depositing unit 110b are described.

The depositing unit (forming means, sputtering means) 110 includes a sputtering device 101, a sputtering shield mask 102, and electrode 103. The depositing unit 110 deposits a coating (hereinafter sometimes called a solder dam coating) made of a material onto which solder is not grafted on one surface 1c through sputtering.

Examples of material (target) of the coating which solder is not grafted to and which is used for formation of the solder dams 4 are: inorganic compound such as SiO₂, SiN, Ta₂O₅ pigment; and organic compounds serving as electrostatic coating material or electrodepositing material having a main component of acrylic resin, epoxy resin, polyester resin, epoxy-polyester resin, acrylic-polyester resin, fluorinated resin or acrylic modified epoxy resin, parylene resin and imide resin.

The sputtering device 101, the sputtering shield mask 102, and the electrode 103 of the first depositing unit 110a are disposed on the different positions from the sputtering device 101, the sputtering shield mask 102, and the electrode 103 of the second depositing unit 110b along the transferring direction of the lead frame 16 so as to be symmetric with respect the lead frame 16.

The sputtering device 101 is disposed so as to face to the surface 1c, on which the solder dam coating on the lead frame 16 is to be formed. To the sputtering device 101, a target material (not illustrated) for the solder dams coating is attached. The electrode 103 is disposed on the opposite side to the sputtering device 101, interposing the lead frame 16 therebetween. The sputtering device 101 and the electrode 103 are coupled to a power source 107, which applies voltage between the sputtering device 101 and the electrode 103.

In the vacuum atmosphere, application voltage between the sputtering device 101 and the electrode 103 causes electrons and ions to fast move between the sputtering device 101 and the electrode 103 and accordingly collide with the target. The electrons and ion moving fast collide with gas molecules and blow off the electrons of the molecules. Upon collision with the target, the ions blow particles of the target (sputtering phenomenon). The blown particles of the target are emitted from the sputtering device 101.

Between the sputtering device 101 and the lead frame 16, the sputtering shield mask 102 is disposed in parallel with the lead frame 16.

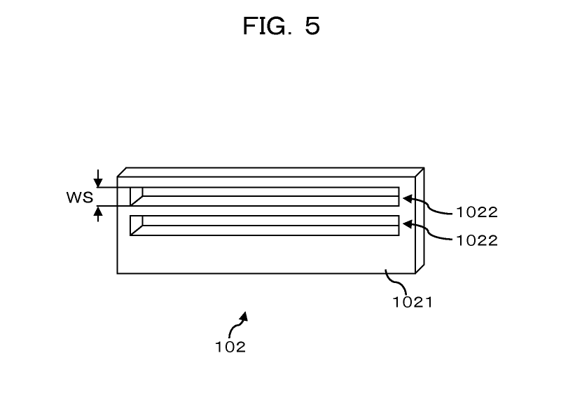

FIG. 5 is a perspective view schematically illustrating the configuration of the sputtering shield mask 102 of the apparatus 10a for forming a solder dam of the first embodiment.

The sputtering shield mask (mask) 102 shields part of the lead frame 16 (leads 1) from the target particle emitted from the sputtering device 101, so that the target particles is deposited only on predetermined part of the lead frame 16 (leads 1). In other words, the sputtering shield mask 102 determines the shape of the solder dam 4 to be formed on the leads 1.

As illustrated in FIG. 5, the sputtering shield mask 102 is fabricated by forming one or more slits 1022 on a plate member 1021. Each slit 1022 takes a form of a rectangular opening formed on the plate member 1021 and functions as a space through which the target particles emitted from the sputtering device 101 pass. Consequently, the slits 1022 correspond to the shapes of the solder dams 4 to be formed on each lead 1 and are therefore in the form of openings having the same widths W of the solder dams 4 on each lead 1. Preferably, each slit 1022 has a width WS (see FIG. 5) in the range of 0.1 mm through 1.0 mm both inclusive.

The number of slits 1022 formed on the plate member 1021 is the same as the number (two in the first embodiment) of the solder dams 4 arranged in rows on each lead 1. If two or more solder dams 4 are formed on each lead 1, the slits 1022 are formed in parallel with one another. The distance between to contiguous slits 1022 corresponds the distance between the contiguous solder dams 4 on each lead 1. The length of the slits 1022 is arbitrarily determined depending on the magnitude of the vacuum chamber 104, the size of the target installed to the sputtering device 101 and other factors.

The sputtering shield mask 102 configured as the above is arranged such that the surface of the plate member 1021 having the slits 1022 faces to the surface 1c of the lead frame 16 as illustrated in FIG. 4. This arrangement causes the slits 1022 of the sputtering shield mask 102 to be opened to the surface 1c of the leads 1.

As illustrated in FIG. 4, the sputtering shield mask 102 is guided along a rail 1024 orthogonal to the transferring direction of the lead frame 16, so that the sputtering shield mask 102 is slidable in the direction of coming near to or apart from the lead frame 16 (i.e., in the transverse direction of FIG. 3). The sputtering shield mask 102 is fixed to any position on the rail 1024 by a non-illustrating fixing device, and can therefore be fixed (arranged) to a position to have a predetermined distance from the lead frame 16.

The operator of the apparatus 10a may move the sputtering shield mask 102 along the rail 1024. Alternatively, the sputtering shield mask 102 may be moved by a mechanical device such as pulse motor, which does not appear in the drawing. Similarly, positioning of the sputtering shield mask 102 may be performed by the operator of the apparatus 10a or by jogging function of the pulse motor.

The rail 1024, the fixing device, and the pulse motor collectively serve to function as the gap adjusting means that adjusts the distance of the gap between the leads 1 and the sputtering shield mask 102.

In order to improve the accuracy of dimension of the solder dams 4 to be formed on each lead 1, a narrower gap between the sputtering shield mask 102 and the lead frame 16 is preferable. For example, the gap between the sputtering shield mask 102 and the lead frame 16 is preferably 0.1 mm or narrower.

As one of the solutions, the sputtering shield mask 102 may be brought into an intimate contact with the lead frame 16, that is, the gap is set to be zero. However, the apparatus 10a for forming a solder dam deposits target particles ejected from the sputtering device 101 through the slits 1022 on the lead frame 16 being transferred as detailed below. If the sputtering shield mask 102 is in intimate contact with the lead frame 16, the sputtering shield mask 102 comes into sliding contact with the leads 1 so that the plate member 1021 of the sputtering shield mask 102 contacts the solder dams 4 (coating of the target particles) formed on the leads 1 and may rub off the solder dams 4 from the leads 1. Accordingly, a predetermined gap is preferably provided between the sputtering shield mask 102 and the lead frame 16. For example, a preferable gap between the sputtering shield mask 102 and the lead frame 16 is approximately 0.05 mm through approximately 0.1 mm both inclusive.

Part of the target particles emitted from the sputtering device 101 reaches the leads 1 through the slits 1022 of the sputtering shield mask 102 and adheres to the leads 1 to form the solder dams 4. The remaining target particles collide with the plate member 1021 and other portion, and thereby do not reach the leads 1 except the portion of the solder dams 4.

The vacuum chamber 104 and the depositing units 110 collectively serve to function as sputtering means that electrostatically depositing the solder dams 4 made of conductive resin material on the leads 1 through the slits 1022 on the sputtering shield mask 102.

1.2 Process to Form a Solder Dam:

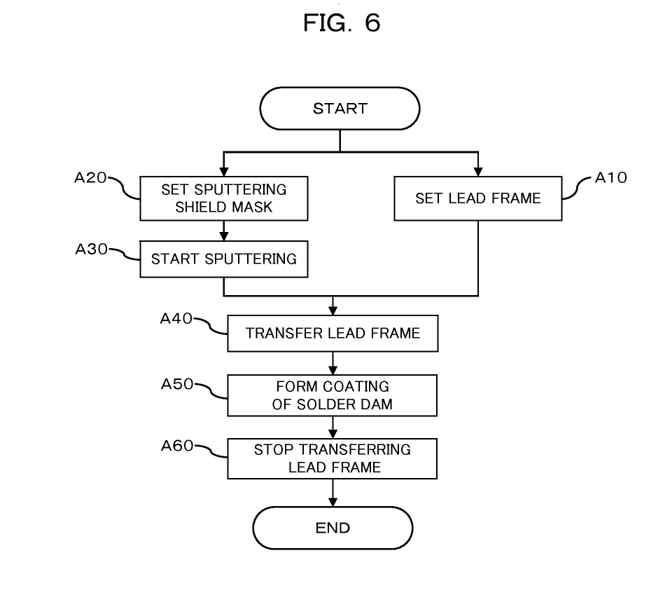

Description will now be made in relation to the process to form the solder dams 4 on the leads 1 in the apparatus 10a for forming a solder dam of the first embodiment with reference to the flow diagram (steps A10 through A60) of FIG. 6.

First of all, the lead frame 16 that is to be subjected to forming solder dams 4 is mounted on the apparatus 10a for forming solder dam (step A10). Specifically, the axis 161a around which the lead frame 16 is reeled is mounted on the mount 160a and the end of the lead frame 16 is unreeled. The unreeled end of the lead frame 16 is inserted into the vacuum chamber 104 through the vacuum chamber shutter 109a; passed through the first depositing unit 110a and the second depositing unit 110b; and is ejected from the vacuum chamber 104 through the vacuum chamber shutter 109b. The end of the lead frame 16 ejected from the vacuum chamber 104 is reeled around the axis 161b of the mount 160b.

Concurrently, the sputtering shield masks 102 are mounted on the first depositing unit 110a and the second depositing unit 110b (step A20). Specifically, in each of the first depositing unit 110a and the second depositing unit 110b, the sputtering shield mask 102 is disposed between the lead frame 16 and the sputtering device 101 so as to be parallel with the lead frame 16 and have a predetermined gap between the lead frame 16 and the sputtering shield mask 102 itself.

Then the power source 107 applies voltage to the electrode 103 and the sputtering device 101 of each of the first depositing unit 110a and the second depositing unit 110b, and sputtering starts (step A30).

The motor 108 rotates the axis 161b to transfer the lead frame 16 at a predetermined speed (step A40).

First, in the first depositing unit 110a, part of the target particles emitted from the sputtering device 101 reaches, through the slits 1022 on the sputtering shield mask 102, one surface of the lead frame 16 being transferred, so that the solder dam coating serving to a function as the solder dam 4 is formed on one surface 1c of each lead 1.

Next, the lead frame 16 is transferred to the second depositing unit 110b, where part of the target particles emitted from the sputtering device 101 reaches, through the slits 1022 on the sputtering shield mask 102, the other surface of the lead frame 16 being transferred, so that the solder dam coating serving to a function as the solder dam 4 is formed on the other surface 1c of each lead 1. Thereby, the solder dam coating is formed on both surfaces 1c of each lead 1 (step A50).

The lead frame 16 having the leads 1 on which the solder dams 4 have been formed is reeled around the axis 161b in the mount 160b. Upon completion of forming the solder dams 4 on the leads 1, the motor 108 is stopped to halt transferring of the lead frame 16, that is, stops the lead frame 16 at a stopping position (step A60). The process to form the solder dams 4 is completed.

The leads 1 on which the solder dams 4 have been formed in the above manner are detached from the lead frame 16 to be used in fabrication of semiconductor package 3.

1-3 Action:

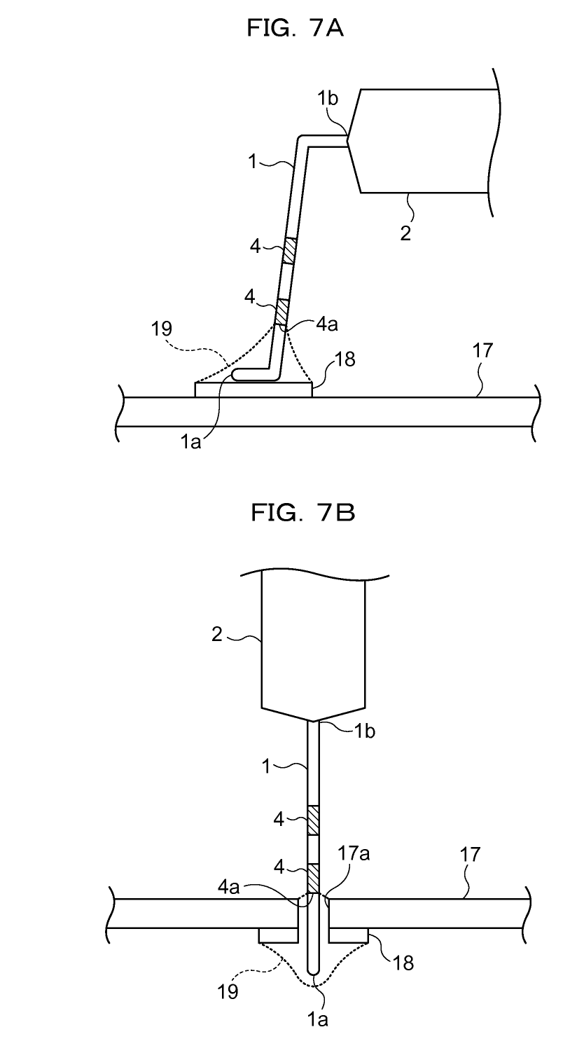

Examples of mounting a semiconductor package 3 including leads 1 with the solder dams 4 formed as the above will be illustrated in FIGS. 7A and 7B.

In surface mounting as illustrated in FIG. 7A, the tip 1a of each lead 1 bent substantially horizontally is mounted on a land 18 of a printed board 17, and the tip 1a and the land 8 are soldered together. In soldering, even if the solder melts on the land 18 is drawn up toward the resin shield 2 through the surfaces 1c and the side faces 1d of the lead 1 under some conditions related to the temperature and other factors, the solder hardly adheres to the solder dams 4 formed at intermediate portions on the lead 1, so that the solder is inhibited from being drawn up toward the resin shield 2.

With this configuration, solder stays below the most lower end 4a of each solder dam 4 and consequently, a good-shaped fillet 19 is formed as illustrated by the broken lines in FIG. 7A.

In through-hole mounting as illustrated in FIG. 7B, the lead 1 is inserted into a through hole 17a that penetrates a printed board 17 in the thickness direction, the tip 1a of the lead 1 and the land 18 disposed on the printed board 17 are soldered together. Even if the solder passes through the thorough hole 17a and is drawn up toward the resin shield 2 through the surfaces 1c and the side faces 1d of the lead 1 under some conditions related to the temperature and other factors, the presence of the solder dams 4 formed on the lead 1 inhibits the solder from being drawn up.

With this configuration, solder stays below the most lower end 4a of each solder dam 4 and consequently, a good-shaped fillet 19 is formed as illustrated by the broken line in FIG. 7B.

1-4 Effects:

According to the apparatus 10a for forming a solder dam of the first embodiment, delicate solder dams 4 can be formed of solder dam coating formed by sputtering process on the surfaces of each lead 1 through the slits 1022 on the sputtering shield mask 102. For example, a number of solder dams 4 can be formed at narrow pitches on a single lead and therefore the apparatus 10a and the method for forming a solder dam through the use of the apparatus 10a can be easily applied to a minute leads arranged in narrow pitches.

Since the sizes of the width and the pitch of the solder dams 4 depend on the shape and the arrangement of the slits 1022 of the sputtering shield mask 102, increase in accuracy of the size and the arrangement of the sputtering shield mask 102 can remarkably improve the accuracy in forming the solder dams 4. Wider slits 1022 forms wider solder dams 4 while narrower slits 1022 forms narrower solder dams 4. Accordingly, the size and the shape of each slit 1022 can be arbitrarily determined so as to conform to the required width W of the solder dam 4. The method of forming a solder dam of the first embodiment can form solder dams 4 precise in size and shape at the accuracy of finishing as small as ±0.05 mm.

Furthermore, forming a gap between the sputtering shield mask 102 and the leads 1 to avoid the physical contact can prevent the solder dams 4 (coating of target particles) formed on the leads 1 from contacting the sputtering shield mask 102 and from consequently being rubbed off. This ensures fabrication of high-quality solder dams 4.

The sputtering shield mask 102 is slidably disposed along the rail 1024 orthogonal to the transferring direction of the lead frame 16 and can be fixed to any position on the rail 1024, so that the gap between the sputtering shield mask 102 and the lead frame 16 can be adjusted to any distance. This configuration makes it possible to form, on the leads 1, solder dams 4 having high accuracy of size.

Since the sputtering shield mask 102 does not physically contact the leads 1, the sputtering shield mask 102 can escape from abrasion, leading to cost reduction for maintenance of the apparatus 10a. Besides, the leads 1 can also escape from deformation and abrasion, ensuring the quality of the resultant semiconductor packages 3.

Using resin material as the target can advantageously form solder dams 4 onto the leads 1 made of any material. In other words, the solder dams 4 can be fixed to the leads 1 by the same interaction of an adhesive, irrespective of the material of the leads 1.

Among various resin materials, a imide resin has a glass transition point of about 230° C., which can satisfactorily endure typical soldering at about 215° C. for about 10 seconds. In using resins other than imide resins, even if the resins degrade due to exposure to high temperature for only a short time, the resins can maintain the function as solder dams. In other words, the solder dams formed of various resin materials afford to realize a function to stop the flow of molten solder.

Further advantageously, resin material has flexibility and therefore hardly cracks and delaminates even when exposed to temperature variation and/or physical stress. In addition, since resin material is low in specific gravity and can be uniformly mixed with ease, resin material is easily formed into the solder dam coating. As a consequence, resin material being used vacuum evaporation scarcely generates uneven coating due to the shape or the position (e.g., inclination) of an object on which a solder dam is to be formed.

The lead frame 16 is transferred in such a posture that the leads 1 extend downward, and the first depositing unit 110a and the second depositing unit 110b form the solder dams 4 each on one of the surface of the leads 1 through sputtering process, so that the solder dams 4 are evenly formed on the both surfaces 1c of the leads 1.

1-5. Modification:

Besides the example explained above, various modifications and changes of the first embodiment can be suggested without departing the gist thereof. Each element and each step in the first embodiment can be selected, unselected, or combined as required.

For example, in the first embodiment, the lead frame 16 is transferred in such a posture that the leads 1 extend downward and the first depositing unit 110a and the second depositing unit 110b forms the solder dams 4 on the both sides of the leads 1 through sputtering. However, transferring of the lead frame 16 and sputtering manner are not limited to those explained as above.

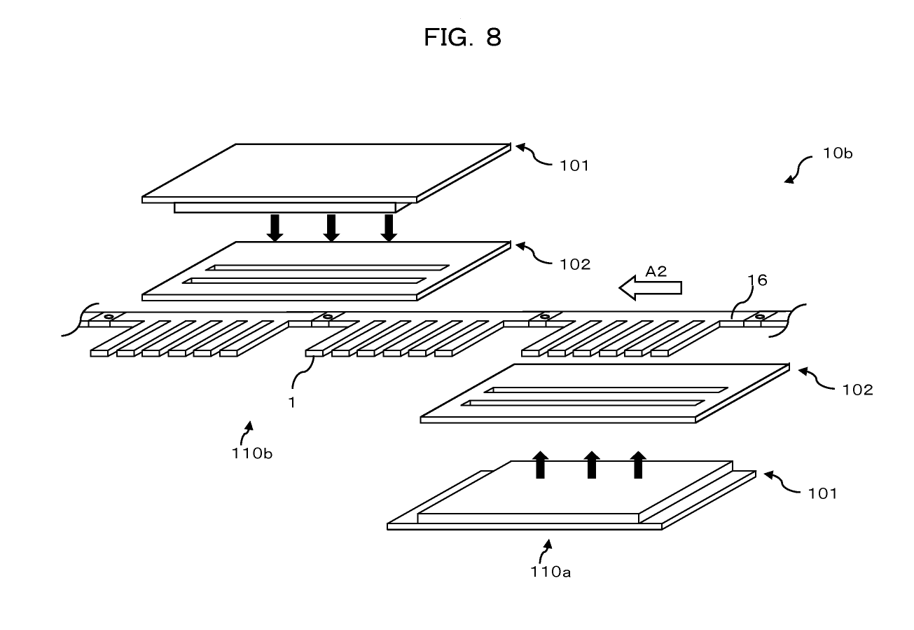

FIG. 8 schematically illustrates depositing units of a first modification to the apparatus for forming a solder dam of the first embodiment. In the modification of FIG. 8, the lead frame 16 is transferred sideways in such a posture that the leads 1 horizontally extend, and the first depositing unit 110a and the second depositing unit 110b form the solder dams 4 respectively on the bottom and the top of the lead frame 16 through sputtering.

Specifically, in the example of FIG. 8, the first depositing unit 110a has an arrangement in which the sputtering device 101 is disposed under the lead frame 16 and the sputtering shield mask 102 is interposed between the sputtering device 101 and the lead frame 16. The second depositing unit 110b is disposed downstream of the first depositing unit 110a (leftward of FIG. 8) and has an arrangement in which the sputtering device 101 is disposed over the lead frame 16 and the sputtering shield mask 102 is interposed between the sputtering device 101 and the lead frame 16.

In other words, the first modification illustrated in FIG. 8 displaces the second depositing unit 110b from the first depositing unit 110a along the transferring direction A2 of the lead frame 16. Namely, the second depositing unit 110b is disposed downstream of the first depositing unit 110a.

For simplification, FIG. 8 illustrates the lead frame 16, and sputtering shield masks 102, and the sputtering devices 101 included in the apparatus 10b for forming a solder dam of the first modification, and omits the remaining elements of the apparatus 10b the same or substantially the same as those of the apparatus 10a for forming a solder dam of the first embodiment.

The apparatus 10b for forming a solder dam of the first modification of the first embodiment have the same effects as the apparatus 10a of the first embodiment.

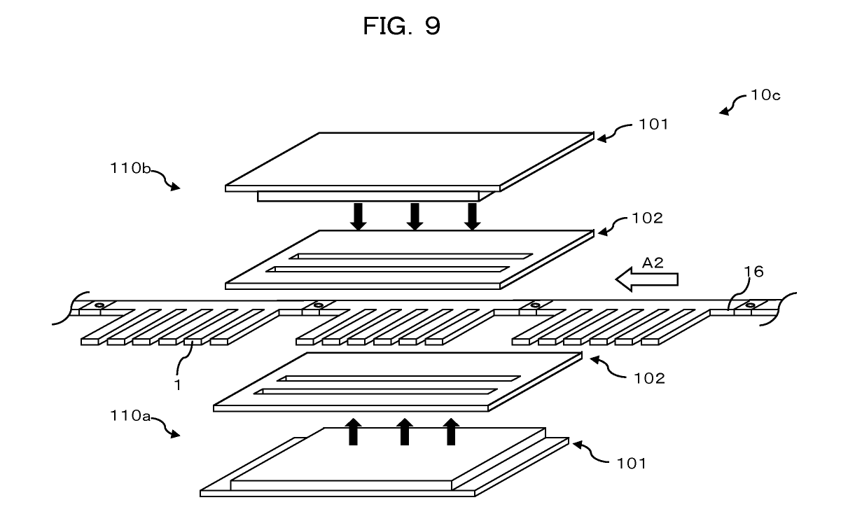

FIG. 9 schematically illustrates depositing units according to a second modification to the apparatus 10a for forming a solder dam of the first embodiment. The apparatus 10c for forming a solder dam of the second modification also transfers the lead frame 16 sideways in such a posture the leads 1 horizontally extend, and the first depositing unit 110a and the second depositing unit 110b form the solder dams 4 respectively on the bottom and the top of the lead frame 16 through.

Specifically, the apparatus 10c disposes the sputtering device 101 of the first depositing unit 110a and the sputtering device 101 of the second depositing unit 110b to face to each other as illustrated in FIG. 9.

In other words, in the second modification of FIG. 9, both the first depositing unit 110a and second depositing unit 110b form the solder dams 4 on the both surfaces 1c at the same or substantially same position along the transferring direction A2 of the lead frame 16.

The second modification of FIG. 9 is realized by adopting magnetron sputtering scheme to the sputtering devices 101. The magnetron sputtering scheme is a technique already known to the public, so detailed description is omitted here.

The apparatus 10c for forming a solder dam of the second modification of the first embodiment have the same effects as the apparatus 10b of the first modification. In addition, the first depositing unit 110a and the second depositing unit 110b of the apparatus 10c form the solder dams 4 on the both surfaces 1c at the same or the substantially same timing, and the time required for forming the solder dams 4 can be shortened. Furthermore, the length of transferring the lead frame 16 can also be shortened, and consequently the apparatus 10c can be small in size.

In the first embodiment and the modifications thereof, the first depositing unit 110a and the second depositing unit 110b are incorporated in the vacuum chamber 104, so that a single-time transferring of the lead frame 16 can form the solder dams 4 on the top and the bottom surfaces (i.e., the two surfaces 1c of the leads 1), but the formation of the solder dams 4 should by no means be limited to this. Alternatively, the apparatus for forming a solder dam may include either first depositing unit 110a or the second depositing unit 110b, so that a first single-time transferring of the lead frame 16 forms the solder dam 4 on either of the two surfaces (i.e., one of the surfaces 1c of lead 1). In succession, the lead frame 16 may be inverted, and a second transferring of the same lead frame 16 may form the solder dam 4 on the other surface. For this purpose, the apparatus for forming a solder dam may include an inversing mechanism to invert the lead frame 16.

Sputtering by the depositing units 110 may be carried out by any of known methods such as diode sputtering, triode sputtering, tetrode sputtering RF sputtering, magnetron sputtering, target facing sputtering, mirror tron sputtering, ECR (Electron Cyclotron Resonance) sputtering, PEMS (Plasma Enhanced Magnetron Sputter), ion-beam sputtering, and dual ion-beam sputtering.

In the first embodiment and the modifications thereof, the depositing units 110 form solder dams 4 on leads 1 through sputtering. The process of forming solder dams 4 is not limited to puttering. Alternatively, the depositing units 110 may form solder dams 4 through vacuum evaporation, other PVD (Physical Vapor Deposition) represented by ion plating, or CVD (Chemical Vapor Deposition).

Further alternatively, the gas supplying unit 106 may supply the vacuum chamber 104 with a minute amount of O₂ and N₂ gasses along with Ar gas, and the depositing units 110 may carry out reactive sputtering (e.g. ITO/TiN) under the presence of these gases.

### 2. Second Embodiment

2-1. Configuration

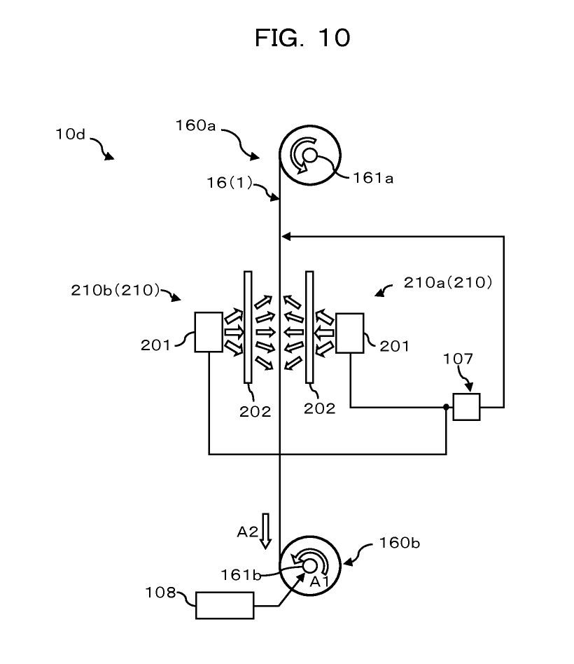

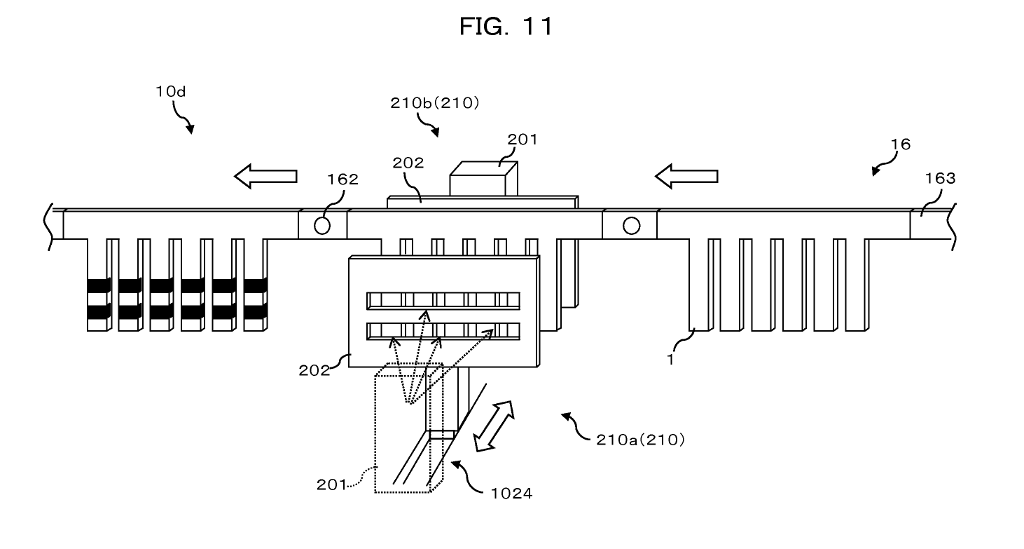

FIG. 10 is a plane view schematically illustrating the configuration of an apparatus 10d for forming a solder dam according to the second embodiment; and FIG. 11 is a perspective view illustrating the depositing unit of the apparatus 10d. The apparatus 10d transfers the lead frame 16 and forms the solder dams 4 on the surfaces 1c of each lead 1 included in the lead frame 16 through electrostatic coating (electrostatic deposition).

Like reference numbers designate similar parts or elements throughout several view of different illustrated examples, so any repetitious description is omitted here.

The apparatus 10d for forming a solder dam as one example of the second embodiment includes, as illustrated in FIG. 10, a first depositing unit 210a, a second depositing unit 210b, and a motor 108.

Also in the apparatus 10d, the lead frame 16 is mounted in such a posture that the leads 1 are extending downward in the vertical direction from the frames 163 as illustrated in FIG. 11 and is transferred the same as the apparatus 10a of the first embodiment.

Furthermore, the apparatus 10d for forming a solder dam includes a non-illustrated transferring guide (non-illustrated transferring guide), which positions the lead frame 16 and guides the lead frame 16 being transferred by the motor 108, and additionally stretches the lead frame 16 similar to the apparatus 10a of the first embodiment.

The first depositing unit 210a forms a solder dam 4 on one surface 1c of each lead frame 16 while the second depositing unit 210b forms a solder dam 4 on the other surface 1c of the lead frame 16.

In the example of FIG. 10, the second depositing unit 210b and the first depositing unit 210a of the apparatus 10d are so as to face to each other, being interposed by the lead frame 16. This configuration forms the solder dams 4 on the both surfaces 1c of each leads 1 at the same position on the transferring direction A2 of the lead frame 16.

Here, the first depositing unit 210a and the second depositing unit 210b are substantially the same in configuration. Hereinafter, the both depositing units are sometimes simply called the “depositing unit 210” for convenience when the common configuration and the common effects of the first depositing unit 210a and the second depositing unit 210b are described.

The depositing unit (forming means, electrostatic coating means) 210 includes a spray 201 and a spray shield mask 202, sprays an electrostatic coating material (paint) to deposit the electrostatic coating material onto one surface 1c of the lead frame 16 through electrostatic coating scheme, so that the solder dam 4 is formed on the surface 1c. The apparatus 10d uses an organic compound which solder is not grafted to and which consequently function as the solder dams 4 when adheres to each lead 1.

A preferable example of the electrostatic coating material is a cation electrostatic coating material having acrylic-polyester as the main component and carbon particles as an additive to enhance the conductivity.

The spray 201 includes a paint atomizer (not illustrated) which atomizes the electrostatic coating material. The paint atomizer may adopt any of various known methods, such as air atomization used for a typical spray gun, airless atomization, electrical atomization, and air-electrical atomization. An alternative atomizer may be electrostatic atomizer that uses repulsion of the electrified coating material itself.

In the apparatus 10d for forming a solder dam, the grounded lead frame 16 (object to be coated) is regarded as the positive electrode while the paint atomizer is regarded as the negative electrode. Application of negative high voltage from the power source 107 to the negative and the positive electrodes generates an electrostatic field between both electrodes, so that the paint particles atomized by the paint atomizer is negatively electrified and thereby efficiently adheres to the coating object of the opposite (positive) electrode.

The atomized paint particles can be electrified in various manners. For example, the paint is first electrified and is then sprayed; or the sprayed paint is provided with charges by corona discharge from an external electrode. Needless to say, various changes and modifications to these examples can be suggested.

In each depositing unit 210, the spray shield mask 202 is interposed between the spray 201 and the lead frame 16 in parallel with the lead frame 16.

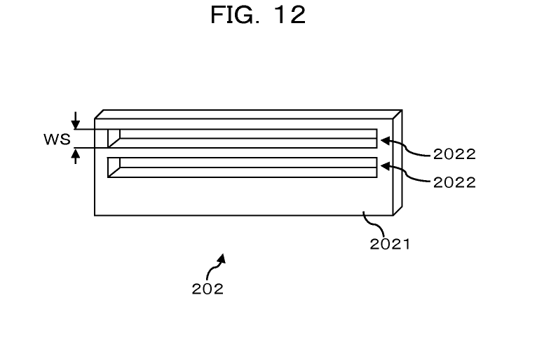

FIG. 12 is a perspective view illustrating the configuration of the spray shield mask 202 of the apparatus 10d for forming a solder dam as one example of the second embodiment.

The spray shield mask (mask) 202 shields part of the lead frame 16 (leads 1) from the paint particles sprayed from the spray 201, so that the coating particles is deposited only on predetermined part of the lead frame 16 (lead 1). In other words, the spray shield mask 202 determines the shape of the solder dam 4 to be formed on the leads 1.

As illustrated in FIG. 12, the spray shield mask 202 is fabricated by forming one or more slits 2022 on a plate member 2021 similar to the sputtering shield mask 102 illustrated in FIG. 5.

Each slit 2022 takes a form of a rectangular opening formed on the plate member 2021 and functions as a space through which the paint particles emitted from the spray 201 pass. Consequently, The slits 2022 correspond to the shapes of the solder dams 4 to be formed on each lead 1 and are therefore in the form of openings having the same widths W of the solder dams 4 on each lead 1. Preferably, each slit 1022 has a width WS (see FIG. 12) in the range of 0.1 mm through 1.0 mm both inclusive.

The number of slits 2022 formed on the plate member 2021 is the same as the number (two in the embodiment) of the solder dams 4 arranged in rows on each lead 1. If two or more solder dams 4 are formed on each lead 1, the slits 2022 are formed in parallel with one another. The distance between to contiguous slits 2022 corresponds the distance between the contiguous solder dams 4 on each lead 1. The length of the slits 1022 is arbitrarily determined depending on the dimension of the space where the apparatus 10d for forming a solder dam is installed and the capability of the spray 201.

The spray shield mask 202 configured as the above is arranged such that the surface of the plate member 2021 having the slits 2022 faces to the surface 1c of the lead frame 16 as illustrated in FIG. 11. This arrangement causes the slits 2022 of the spray shield mask 202 to be opened to the surface of the leads 1.

Additionally, the spray shield mask 202 is guided by a rail 1024 orthogonal to the transferring direction of the lead frame 16, so that the spray shield mask 202 is slidable in the direction of coming near to or apart from the lead frame 16 (i.e., in the transverse direction of FIG. 10). The spray shield mask 202 is fixed to any position on the rail 1024 by a non-illustrating fixing device, and can therefore be fixed (arranged) to a position to have a predetermined distance from the lead frame 16.

The operator of the apparatus 10d may move the spray shield mask 202 along the rail 1024. Alternatively, the spray shield mask 202 may be moved by a mechanical device such as pulse motor, which does not appear in the drawing. Similarly, positioning of the spray shield mask 202 may be performed by the operator of the apparatus 10d or by jogging function of the pulse motor.

The rail 1024, the fixing device and the pulse motor collectively serve to function as the gap adjusting means that adjusts the distance of the gap between the leads 1 and the spray shield mask 202.

In order to improve the accuracy of dimension of the solder dams 4 to be formed on each lead 1, a narrower gap between the spray shield mask 202 and the lead frame 16 is preferable. For example, the gap between the spray shield mask 202 and the lead frame 16 is preferably 0.1 mm or narrower.

As one of the solutions, the spray shield mask 202 may be brought into an intimate contact with the lead frame 16, that is, the gap is set to be zero. However, the apparatus 10d for forming a solder dam deposits the paint particles sprayed from the spray 201 through the slits 2022 on the lead frame 16 being transferred as detailed below. If the spray shield mask 202 is in intimate contact with the lead frame 16, the spray shield mask 202 comes into sliding contact with the leads 1 so that the plate member 2021 of the spray shield mask 202 contacts the solder dams 4 (coating formed of the paint particles) formed on the leads 1 and may rub off the solder dams 4 from the leads 1. Accordingly, a predetermined gap is preferably provided between the spray shield mask 202 and the lead frame 16. For example, a preferable gap between the spray shield mask 202 and the lead frame 16 is approximately 0.05 mm through approximately 0.1 mm both inclusive.

Part of the paint particles sprayed from the spray 201 reaches the leads 1 through the slits 2022 of the spray shield mask 202 and adheres to the leads 1 to form the solder dams 4. The remaining paint particles collide with the plate member 2021 and other portion, and thereby do not reach the leads 1 except the portion of the solder dams 4.

As the above, the depositing units 210 collectively function as electrostatic coating means that electrostatically deposits solder dams 4 made of conductive resin material on the leads 1 through the slits 2022 on the spray shield mask 202.

2.2 Process to Form a Solder Dam:

Also in the apparatus 10d for forming a solder dam of one example of the second embodiment having the above configuration, the solder dams 4 are formed onto the leads 1 through the same procedure of the flow diagram FIG. 6 as performed in the apparatus 10a of the first embodiment.

Specifically, after the lead frame 16 and the spray shield mask 202 are mounted to the apparatus 10d, the spray 201 starts spraying the paint particles.

The motor 108 rotates the axis 161b to transfer the lead frame 16 at a predetermined speed, and during the transfer, the solder dams 4 are formed on the leads 1.

In the first depositing unit 210a of the apparatus 10d, part of the paint particles sprayed from the spray 201 reaches, through the slits 2022 on the spray shield mask 202, one surface of the lead frame 16 being transferred, so that the solder dam coating serving to a function as the solder dam 4 is formed on one surface 1c of each lead 1.

At the same or substantially the same timing, also in the second depositing unit 210b, part of the paint particles sprayed from the spray 201 reaches, through the slits 2022 on the spray shield mask 202, the other surface 1c of the lead frame 16 being transferred, so that the solder dam coating serving to a function as the solder dam 4 is formed on the other surface 1c of each lead 1. Consequently, the solder dams 4 are formed on both surfaces 1c of each lead 1.

The coating material adhering to the surfaces 1c and the side faces 1d of each lead 1 is air-dried during the subsequent transferring process. Alternatively, the coating material applied to the leads 1 may be dried with a dryer. The coating material dried and fixed on the leads 1 functions as the solder dams 4.

Upon completion of forming the solder dams 4 on the leads 1, the lead frame 16 is stopped at a stopping position to complete the process to form the solder dams 4.

The leads 1 on which the solder dams 4 have been formed in the above manner are detached from the lead frame 16 to be used in fabrication of a semiconductor package 3.

A semiconductor package 3 having the solder dams 4 formed by the apparatus 10d for forming a solder dam of the second embodiment has the same effects as those illustrated in FIGS. 7A and 7B.

2-3. Effects

As detailed above, the apparatus 10d for forming a solder dam of an example of the second embodiment attains the same effects and advantages as those of the apparatus 10a of the first embodiment.

According to the apparatus 10d for forming a solder dam of the second embodiment, delicate solder dams 4 can be formed of solder dam coating by electrostatic coating process on the surfaces of each lead 1 through the slits 2022 on the spray shield mask 202. For example, a number of solder dams 4 can be formed at narrow pitches on a single lead and therefore the apparatus 10d and the method for forming a solder dam through the use of the apparatus 10d can be easily applied to a minute leads arranged in narrow pitches.

Since the sizes of the width and the pitch of the solder dams 4 depend on the shape and the arrangement of the slits 2022 of the spray shield mask 202, increase in accuracy of the size and the arrangement of the spray shield mask 202 can remarkably improve the accuracy in forming the solder dams 4.

Wider slits 2022 forms wider solder dams 4 while narrower slits 2022 forms narrower solder dams 4. Accordingly, the size and the shape of each slit 2022 can be arbitrarily determined so as to conform to the required width W of the solder dam 4. The method of forming a solder dam of the second embodiments can form solder dams 4 having precise in size and shape at the accuracy of finishing as small as ±0.05 mm.

Furthermore, forming a gap between the spray shield mask 202 and the leads 1 to avoid the physical contact can prevent the solder dams 4 (coating made of the paint particles) formed on the leads 1 from contacting the spray shield mask 202 and from consequently being rubbed off. This ensures high-quality solder dams 4.

The spray shield mask 202 is slidably disposed on the rail 1024 orthogonal to the transferring direction of the lead frame 16 and can be fixed to any position along the rail 1024, so that the gap between the spray shield mask 202 and the lead frame 16 can be adjusted to any distance. This configuration makes it possible to form, on the leads 1, solder dams 4 having high accuracy of size.

Since the spray shield mask 202 does not physically contact the leads 1, the spray shield mask 202 can escape from abrasion, leading to cost reduction for maintenance of the apparatus 10d. Besides, the leads 1 can also escape from deformation and abrasion, ensuring the quality of the resultant semiconductor packages 3.

Further, using resin material as the electrostatic coating material ensures the same effects and advantages of the apparatus 10a of the foregoing first embodiment.

In addition, the first depositing unit 210a and the second depositing unit 210b of the apparatus 10d form the solder dams 4 on the both surfaces 1c at the same or the substantially same timing, and the time required for forming the solder dams 4 can be short. Furthermore, the length of transferring the lead frame 16 can also be short, and consequently the apparatus 10c can be small in size.

### 3. Third Embodiment

3-1. Configuration:

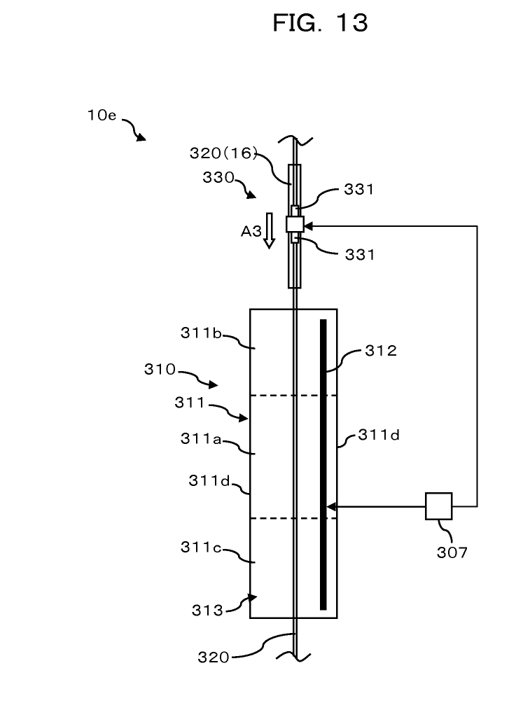

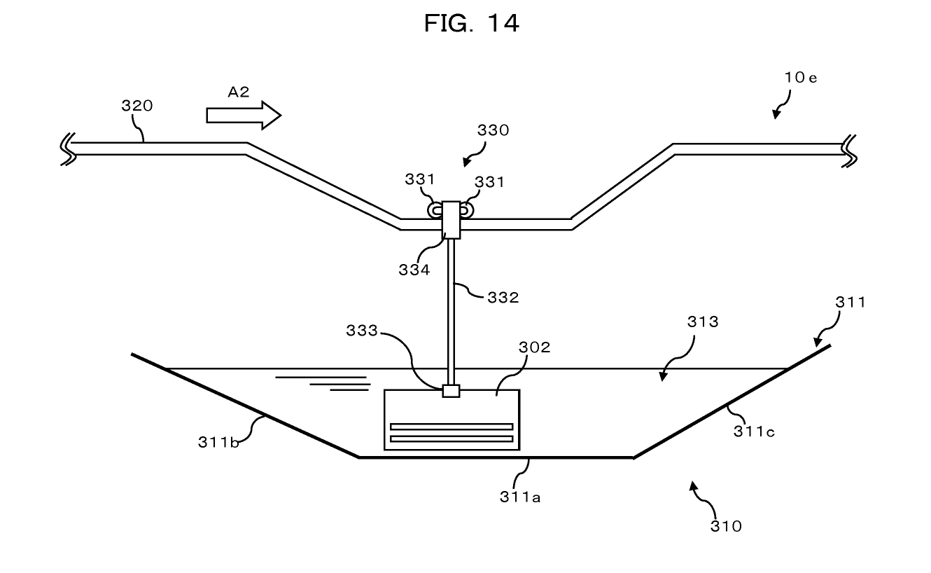

FIG. 13 is a plane view schematically illustrating an apparatus 10e for forming a solder dam as one example of the third embodiment; and FIG. 14 is a side view schematically illustrating the depositing unit 310 of the apparatus 10e. The apparatus 10e transfers the lead frame 16 and forms the solder dams solder dam 4 on surfaces 1c of each lead 1 included in the lead frame 16 through electrodeposition.

Like reference numbers designate similar parts or elements throughout several view of different illustrated examples, so any repetitious description is omitted here.

As illustrated in FIG. 13, the apparatus 10e for forming a solder dam as one example of the third embodiment includes a depositing unit 310 and a transferring rail 320.

The depositing unit (forming means, electrodepositing means) 310 forms solder dam 4 on the surfaces 1c of each leads 1, and for this purpose, includes a depot 311 and an electrode 312.

The depot 311 includes a bottom 311a, inclined planes 311b and 311c, and two side walls 311d, and contains electrodepositing solution 313 in the space enclosed by the bottom, the planes and the walls.

The bottom 311a has a rectangular shape has one side coupled to the rectangular inclined plane 311b. The side of the inclined plane 311b opposite to the side coupled to the bottom 311a is arranged at a higher position than the coupled side, so that the inclined plane 311b downward inclines at a predetermined angle toward the bottom 311a. To the side of the bottom 311a opposite to the side coupled to the inclined plane 311b, the inclined plane 311c is coupled. Similarly, the side of the inclined plane 311c opposite to the side coupled to the bottom 311a is arranged at a higher position than the coupled side, so that the inclined plane 311c downward inclines at a predetermined angle toward the bottom 311a.

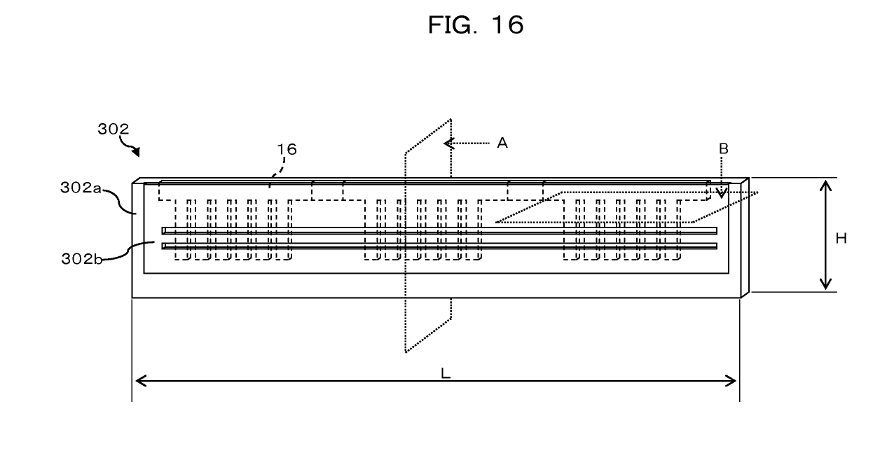

The side walls 311d face to each other and stand so as to sandwich the bottom 311a, the inclined planes 311b and 311c. The height of the side walls 311d is set to be larger than the height H (see FIG. 16) of an electrodeposition shield mask 302 to be detailed below. The distance between two opposite sides of the bottom 311a coupled to the inclined plane 311b and the inclined plane 311c (that is, the length of the sides along the side walls 311d) is set be larger than the length L (see FIG. 16) of the electrodeposition shield mask 302 along the transferring direction.

With this configuration, the electrodeposition shield mask 302 can be accommodated in a space enclosed by the bottom 311a, the inclined planes 311b and 311c, and the side walls 311d.

Furthermore, the electrode 312 is disposed along at least one of the side walls 311d in the depot 311. The power source 307 is connected to the electrode 312 and applies electric power to the electrode 312.

The electrodepositing solution 313 is contained in the depot 311. The electrodepositing solution 313 is prepared by, for example, dissolving or dispersing paint in water at a solid concentration of 8 through 20%. The electrodepositing solution 313 is a solution in which an organic compound which solder is not grafted to is dissolved, and is exemplified by a cation electrodepositing paint containing acrylic-modified epoxy resin.

Table 1 illustrates an example of components contained in a cation electrodeposition paint used for electrodeposition material in the apparatus 10e of the third embodiment.

TABLE 1

| COMPONENT OF CATION | | |
|---|---|---|
| ELECTRODEOISTING COATING | CONTENT | |
| ACRYLIC MODIFIED EPOXY RESIN | 51.4 | wt/% |
| PIGMENT | 14.6 | wt/% |
| CURING ACCELERATOR | 0.5 | wt/% |
| ADDITIVE | 1.0 | wt/% |
| NEUTRALIZER | 1.7 | wt/% |
| SOLVENT | 30.8 | wt/% |
| TOTAL | 100.0 | wt/% |

The depot 311 further includes a pump and a tank (both not illustrated) to circulate and replenish the electrodepositing solution 313.

The transferring rail 320 guides the lead frame 16 to which the electrodeposition shield mask 302 is attached, and is suspend over the depot 311 so as to longitudinally traverse, in sequence, the inclined plane 311b, the bottom 311a, and the inclined plane 311c as illustrated in FIGS. 13 and 14.

The transferring rail 320, as illustrated in FIG. 14, is set to have a difference in height over the depot 311 which difference conforms the shapes of the inclined plane 311b, the bottom 311a, and the inclined plane 311c. Specifically, the transferring rail 320 inclines over the inclined plane 311b and the inclined plane 311c so as to be in parallel to the inclined plane 311b and the inclined plane 311c and is horizontally disposed over the bottom 311a so as to be in parallel to the bottom 311a.

This configuration forms the transferring rail 320 to have a substantial constant vertical distance to the inclined plane 311b, the bottom 311a, and the inclined plane 311c over the depot 311.

To the transferring rail 320, a supporting unit 330 is attached, which transfers the lead frame 16 having the electrodeposition shield mask 302 attached to the lead frame 16 along the transferring rail 320 in such a posture that the lead frame 16 is suspended downward.

As illustrated in FIG. 14, the supporting unit 330 includes a holder 333, a supporting bar 332, a connector 334, and rollers 331. Specifically, in the supporting unit 330, the holder 333 is attached to one end (lower end in FIG. 14) of the supporting bar 332, and the rollers 331 and the connector 334 are attached to the other end (upper end in FIG. 14).

The holder 333 holds the lead frame 16 having the electrodeposition shield mask 302 attached thereto. For example, the holder 333 fixes the lead frame 16 to the supporting bar 332 by clamping the electrodeposition shield mask 302.

The rollers 331 are disposed on the transferring rail 320 and is configured to be movable the transferring rail 320 along the extending direction of the transferring rail 320 (i.e., the transferring direction; see arrow A3 in FIG. 13). In the example of FIG. 14, the two rollers 331 are disposed in parallel to each other in such a posture that the respective axes of rotation are orthogonal to the transferring direction.

The connector 334 connects the rollers 331 with the supporting bar 332. In the example of FIG. 14, the connector 334 surrounds the rollers 331 and the transferring rail 320 to function as dropping preventing device that prevents the rollers 331 from dropping off the transferring rail 320.

The supporting bar 332 has a length which allows the lead frame 16, which the supporting unit 330 is supporting and to which the electrodeposition shield mask 302 is attached, to be immersed in the electrodepositing solution 313 contained in the depot 311 and concurrently which length avoids the contact of the same lead frame 16 with the bottom 311a and the inclined planes 311b and 311c.

The lead frame 16 being held by the supporting unit 330 is supplied with electric power from the power source 307.

The supporting unit 330 travels along the transferring rail 320 at a predetermined speed with the aid of a non-illustrating transferring device. The transferring device may be a motor that rotates the rollers 331, or a non-illustrated towing device that tows the supporting unit 330 along the transferring rail 320. Any device to accomplish the purpose can be applied to the transferring device.

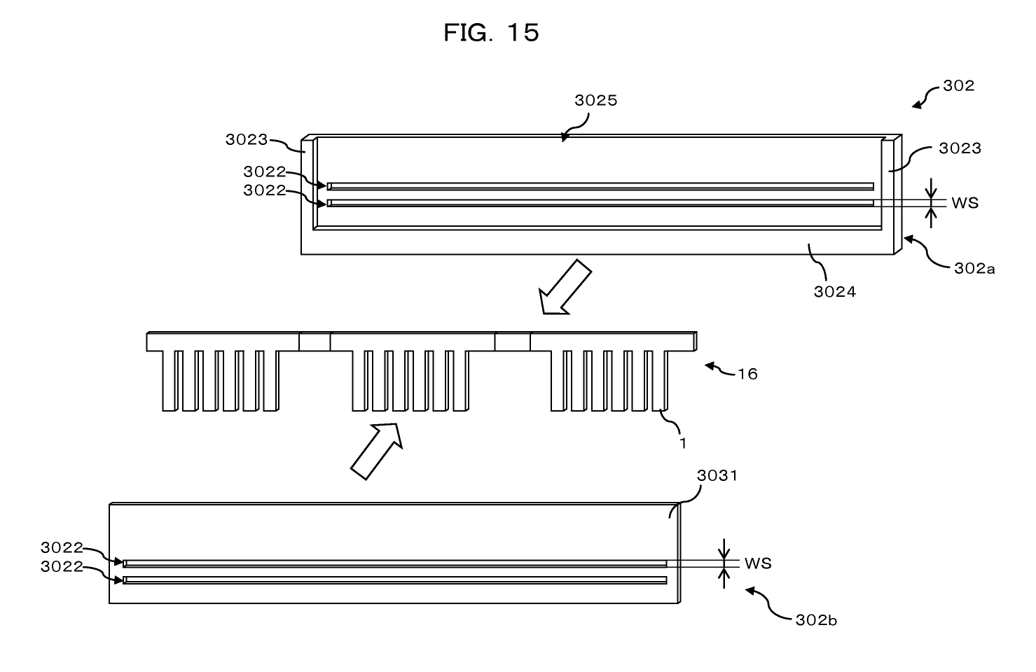

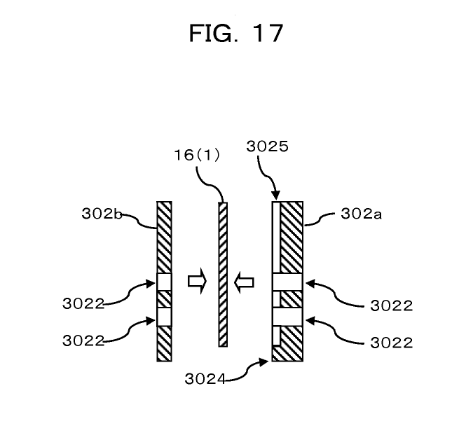

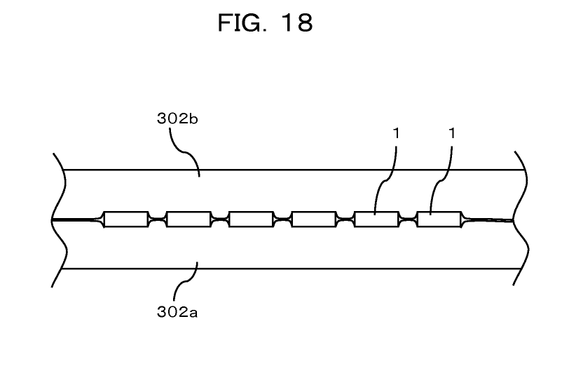

FIGS. 15 through 18 illustrate the configuration of the electrodeposition shield mask 302 used in the apparatus 10e for forming a solder dam serving as one example of the third embodiment: FIG. 15 is an exploded perspective view of the electrodeposition shield mask 302; FIG. 16 is a perspective view of the electrodeposition shield mask 302; FIG. 17 is a sectional view of a section A of FIG. 16; and FIG. 18 is another sectional view of a section B of FIG. 16.

The electrodeposition shield mask (mask) 302 is mounted on the lead frame 16 and prohibits the electrodepositing solution 313 from adhering to part of the lead frame 16 (leads 1) except for desired portions (i.e., portions to form the solder dams 4) when the lead frame 16 is immersed in the electrodepositing solution 313 contained in the depot 311. In other words, the electrodeposition shield mask 302 allows the electrodepositing solution 313 to adhere only to the desired portions on the lead frame 16 (the leads 1) and thereby determines the shapes of the solder dams to be formed on each lead 1.

As illustrated in FIG. 15, the electrodeposition shield mask 302 includes a mask base 302a and a mask cover 302b, which cooperatively clamps the lead frame 16 cut into a predetermined length at the frames 163 to be thereby mounted on the lead frame 16.

The mask base 302a takes a form of a rectangular plate member 3021 which is larger than the lead frame 16 and which has one or more slits 3022 formed thereon. On the end of one of the longer sides and the ends of both shorter sides of the plate member 3021, protrusions 3024, 3023, and 3023 are formed, respectively, which are same in height as the thickness of the mask cover 302b and which project in the direction of the normal of the surface of the plate member 3021.

On the circumference of the plate member 3021, the protrusions 3024, 3023, and 3023 project in a U shape. As illustrated in FIGS. 15 and 17, the mask cover 302b is fit into a region having three sides are enclosed by the protrusions 3024, 3023, and 3023 of the plate member 3021, interposing the lead frame 16 between the plate member 3021 and the mask cover 302b. Thereby, the lead frame 16 is accommodated in the electrodeposition shield mask 302, as illustrated in FIG. 16. Hereinafter, the region having three sides are enclosed by the protrusions 3024, 3023, and 3023 is sometimes called a lead-frame accommodating region 3025.

The slits 3022 are rectangular openings formed on the lead-frame accommodating region 3025 of the plate member 3021.

In the depot 311, the electrodepositing solution 313 is immersed through the slits 3022 to adhere to the lead frame 16 (leads 1). At the slits 3022, the coating components (paint coating) to be serve as the solder dams 4 is deposited from the electrodepositing solution 313 adhering to the leads 1 as detailed below. Consequently, the shapes of slits 3022 correspond to the shapes of the solder dams 4 to be formed on each lead 1 and are therefore openings having the same widths W of the solder dams 4 on each lead 1. Preferably, each slit 3022 has a width WS (see FIG. 15) in the range of 0.1 mm through 1.0 mm both inclusive.

The number of slits 3022 formed on the plate member 3021 is the same as the number (two in the first embodiment) of the solder dams 4 arranged in rows on each lead 1. If two or more solder dams 4 are formed on each lead 1, the slits 3022 are formed in parallel with one another. The distance between two contiguous slits 3022 corresponds the distance between the contiguous solder dams 4 on each lead 1. The length of the slits 3022 is arbitrarily determined depending on the magnitude of the bottom 311a of the depot 311 and the size of lead frame 16.

As illustrated in FIG. 15, the mask cover 302b takes a form of a rectangular plate member 3031 which is larger than the lead frame 16 and which has one or more slits 3032 formed thereon as many as the slits 3022 formed on the mask base 302a. The plate member 3031 is the same in shape as the lead-frame accommodating region 3025 and is configured to fittable in the lead-frame accommodating region 3025 of the mask base 302a, interposing the lead frame 16 between the mask cover 302b and the lead-frame accommodating region 3025.

Also on the mask cover 302b, slits 3022 as many as the slits 3022 formed on the plate member 3021 are formed. The slits 3022 on the mask cover 302b are formed at positions facing to the slit 3022 on the mask base 302a when the mask cover 302b is fitted into the lead-frame accommodating region 3025, interposing the lead frame 16, as illustrated in FIG. 17.

The mask base 302a, the mask cover 302b, and the lead frame 16 are fixed together by a non-illustrated fixing device in a state of interposing the lead frame 16 between the mask base 302a and the mask cover 302b. The fixing device can be realized by any of screws, clamps and others and detailed description thereof is omitted here.

The mask base 302a and the mask cover 302b are made of oil-resistant elastic material, such as oil-resistant rubber. Preferable oil-resistant rubber materials are listed below:

(1) EPM.EPDM (ethylene-propylene rubber)
(2) IIR (butyl rubber)
(3) NBR (nitrile rubber)
(4) HNBR (hydrogenated nitrile rubber)
(5) fluorine rubber

FKM (vinylidene fluoride rubber)

FEPM (tetrafluoroethylene-propylene rubber)

FFKM (tetrafluoroethylene-perfluorovinyl ether rubber)

(6) CR (chloroprene rubber)
(7) ACM (acrylic rubber)
(8) SR (silicone rubber)

While the lead frame 16 is being stored in the lead-frame accommodating region 3025, the mask cover 302b is pressed against the mask base 302a. Pressing the mask base 302a and the mask cover 302b both formed of elastic rubber material against each other allows the mask base 302a and the mask cover 302b to elastically deform and thereby fill into the spaces between contiguous leads 1 in a region other than the slits 3022, as illustrated in FIG. 18.

For the above, the electrodepositing solution 313 does not adhere to the side faces 1d except for the portion exposed through the slits 3022.

Then, the electrodeposition shield mask 302 in which the lead frame 16 is accommodated in the lead-frame accommodating region 3025 and is pressed from both sides by the mask base 302a and the mask cover 302b is immersed into the depot 311 containing the electrodepositing solution 313. Consequently, the electrodepositing solution 313 reaches the leads 1 through the slits 3022 on the electrodeposition shield mask 302.

Under this state, regarding the lead frame 16 (lead 1: object to be coated) as a negative electrode (−) and regarding the electrode 321 disposed in the depot 311 as a positive electrode (+), direct voltage (e.g. 100 V through 300 V) is applied to feed electric current between the lead frame 16 and the electrode 321 from the power source 307, so that insoluble coating is deposited on a portion of the lead frame 16 (leads 1) immersed into the electrodepositing solution 313.

Specifically, insoluble coating is deposited on a portion of leads 1 which portion corresponds to the opening of the slits 3022 of electrodeposition shield mask 302 and servers as the solder dams 4. On the other hand, since the remaining portion of the lead frame 16 is in intimate contact with the electrodeposition shield mask 302, the portion is not immersed in the electrodepositing solution 313. As a result, insoluble coating is not formed on a portion other than the portion for the solder dams 4 on each lead 1.

The depositing unit 310 functions as electrodepositing means that electrodeposits electrified resin material on the leads 1 through the slits 3022 formed on the electrodeposition shield mask 302.

2-2. Process to Form a Solder Dam:

In the apparatus 10e for forming a solder dam as an example of the third embodiment, the electrodeposition shield mask 302 is first attached to the lead frame 16. At a predetermined installation position on the transferring rail 320, the electrodeposition shield mask 302 accommodating the lead frame 16 is installed to the holder 333 of the supporting unit 330.

After that, the non-illustrated transferring device transfers the supporting unit 330 along the transferring rail 320 at a predetermined speed and immerses the electrodeposition shield mask 302 in the electrodepositing solution 313 in the depot 311.

Then, the power source 307 applies direct voltage (e.g., 100 V through 300 V) to feed electric current between the lead frame 16 and the electrode 312, so that insoluble coating is deposited on a portion of the lead frame 16 (leads 1) immersed into the electrodepositing solution 313. Thereby, the solder dams coating is formed on the surfaces 1c and the side faces 1d of each lead 1.

Then, the electrodeposition shield mask 302 accommodating the lead frame 16 is risen from the depot 311 and undeposited electrodepositing solution 313 is washed off with water. In succession, the lead frame 16 is dried in a non-illustrated drying oven so that the adhering electrodepositing solution 313 is heat-cured to serve as coating, which functions as the solder dams 4 on each lead 1.

The leads 1 on which the solder dams 4 have been formed in the above manner are detached from the lead frame 16 to be used in fabrication of semiconductor package 3.

A semiconductor package 3 having the solder dams 4 formed by the apparatus 10e for forming a solder dam of the second embodiment has the same effects as those illustrated in FIGS. 7A and 7B.

3-3. Effects:

As detailed above, the apparatus 10e for forming a solder dam of an example of the third embodiment attains the same effects and advantages as the apparatus 10a of the first embodiment.

According to the apparatus 10e for forming a solder dam of the third embodiment, delicate solder dams 4 can be formed of solder dam coating deposited through electrodeposition process on the surfaces of each lead 1 through the slits 3022 on the electrodeposition shield mask 302. For example, a number of solder dams 4 can be formed at narrow pitches on a single lead and therefore the apparatus 10e and the method for forming a solder dam through the use of the apparatus 10d can be easily applied to a minute leads arranged in narrow pitches.

Since the sizes of the width and the pitch of the solder dams 4 depend on the shape and the arrangement of the slits 3022 of the electrodeposition shield mask 302, increase in accuracy of the size and the arrangement of the electrodeposition shield mask 302 can remarkably improve the accuracy in forming the solder dams 4. Wider slits 3022 forms wider solder dams 4 while narrower slits 3022 forms narrower solder dams 4. Accordingly, the size and the shape of each slit 3022 can be arbitrarily determined so as to conform to the required width of the solder dam 4. The method of forming a solder dam of the third embodiments can form solder dams 4 having precise in size and shape at the accuracy of finishing as small as ±0.05 mm.

Being made of elastic material, the mask cover 302b and the mask base 302a press each lead 1 from the both surfaces 1c and elastically deform so as to fill the spaces between contiguous leads 1. The deformation can prevent a solder dam 4 from being formed on a region not corresponding to the slits 3022, and the quality of the leads 1 can be further improved.

Using resin material as the electrodepositing solution 313 ensures the same effects and advantages as those derived by the apparatus 10a for forming a solder dam of the first embodiment and other embodiments.

### 4. Others

Besides the embodiments and the modifications thereof detailed above, various changes and modifications can be suggested without departing from the sprit of the embodiments. The configuration and the process of the foregoing embodiments can be selected, unselected, and combined according to the requirement.

For example, in the first embodiment and the modifications thereof, the sputtering shield mask 102 includes two slits 1022, which forms two solder dams 4 on each individual lead 1. The number of solder dams 4 formed on each lead 1 is not limited to two. Alternatively, the sputtering shield mask 102 may have a single slit 1022 or three or more slits 1022 to form a single solder dam 4 or three or more solder dams 4 on each lead 1.

Also the second and the third embodiments, the spray shield mask 202 and the mask base 302a and the mask cover 302b may each have a single slit 2022 or 3022 or three or more slits 2022 or 3022 to form a solder dam 4 or three or more solder dams 4 on each lead 1.

Furthermore, in the first and the second embodiments, the sputtering shield mask 102 and the spray shield mask 202 are disposed so as to have a predetermined gap from the lead frame 16 when the solder dam coating is formed. However, the arrangement of the masks are not limited to this.

Alternatively, when the solder dam coating to be formed, the sputtering shield mask 102 and the spray shield mask 202 may be brought into intimate contact with the lead frame 16 and may be move for a predetermined distance in conjunction with transferring of the lead frame 16. Upon completion of forming the solder dam coating on the lead frame 16, the sputtering shield mask 102 and the spray shield mask 202 may be separated from the lead frame 16. This manner makes it possible to the solder dam coating formed on each lead 1 from contacting the sputtering shield mask 102 and the spray shield mask 202, which contact has a possibility of rubbing off the solder dam coating. As a consequence, a high-quality solder dam 4 can be formed.

In the foregoing embodiments and the modifications thereof, the solder dams 4 is formed on the lead frame 16 including two or more leads 1 extends parallel in the same direction from the strip-shaped frame 163 at regular intervals.

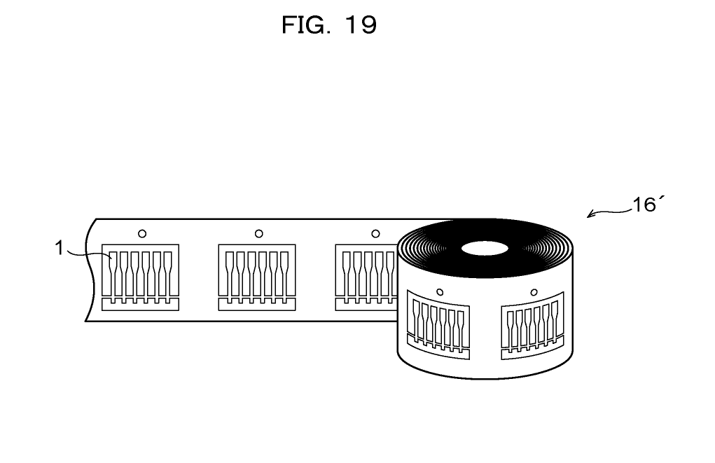

FIG. 19 is a perspective view of the frame to be used in a method of forming solder dams according to a modification.

For example, as illustrated in FIG. 19, the solder dams 4 may be formed on a strip-shaped lead frame 16′ including a number of leads 1 not punched out of the metal sheet yet.

The disclosed technique can enhance the accuracy of positioning to form solder dams on leads 1 so that delicate solder dams can be formed.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment (s) has (have) been described in detail, it should be understood that the various changes, substitutions, and alterations could be made hereto without departing from the spirit and scope of the invention.

What is claimed is:

1. An apparatus for forming a solder dam on each lead of an electronic device, the apparatus comprising:
a mask having one or more slits; and
forming means that forms the solder dam made of non-metal material on the lead of the electronic device through the slits of the mask.

2. The apparatus according to claim 1, wherein the forming means comprises sputtering means that deposits the solder dam made of an inorganic compound on the lead of the electronic device through the slits of the mask by sputtering.

3. The apparatus according to claim 1, wherein the forming means comprises electrostatic coating means that electrostatically depositing the solder dam made of conductive resin material on the lead of the electronic device through the slits of the mask.

4. The apparatus according to claim 1, wherein the mask is separated by a predetermined gap from the lead of the electronic device when the forming means is forming the solder dam.

5. The apparatus according to claim 4, wherein the predetermined gap between the mask and the lead of the electronic device is 0.1 mm or narrower.

6. The apparatus according to claim 1, further comprising gap adjusting means that adjusts a size of a gap between the lead of the electronic device and the mask.

7. The apparatus according to claim 1, wherein the forming means comprises electrodepositing means that electrodeposites electrified resin material on the lead of the electronic device through the slits of the mask.

8. The apparatus according to claim 1, wherein the slits have widths corresponding to the widths of the solder dam to be formed on the lead of electronic devices.

9. The apparatus according to claim 1, wherein the slits each have a width in a range of 0.1 mm through 1.0 mm both inclusive.

10. A method for forming a solder dam on each lead on an electronic device, the method comprising:
overlaying the lead with a mask having one or more slits;
forming the solder dam made of non-metal material on the lead of the electronic device through the slits of the mask.

11. The method according to claim 10, wherein the step of forming comprises depositing the solder dam made of an inorganic compound on the lead of the electronic device through the slits of the mask by sputtering.

12. The method according to claim 10, wherein the step of forming comprises electrostatically depositing the solder dam made of conductive resin material on the lead of the electronic device through the slits of the mask.

13. The method according to claim 10, wherein, in the step of overlaying, disposing the mask to have a predetermined gap from the lead of the electronic device

14. The method according to claim 13, wherein, in the step of overlaying, disposing the mask to have a gap of 0.1 mm or narrower from the lead of the electronic device.

15. The method according to claim 10, further comprising adjusting a size of a gap between the lead of the electronic device and the mask.

16. The method according to claim 10, wherein the step of forming comprises electrodepositing electrified resin material on the lead of the electronic device through the slits of the mask.

17. The method according to claim 10, wherein the slits have widths corresponding to the widths of the solder dam to be formed on the lead of electronic devices.

18. The method according to claim 10, wherein the slits each have a width in a range of 0.1 mm through 1.0 mm both inclusive.
